(19) United States
(12) Patent Application Publication
(10) Pub. No.: US 2025/0374670 A1
(43) Pub. Date: Dec. 4, 2025

(54) TRACK STEALING FOR STANDARD CELL HEIGHT COMPACTION

(71) Applicant: QUALCOMM Incorporated, San Diego, CA (US)

(72) Inventors: Shreesh NARASIMHA, Charlotte, NC (US); Yan SUN, San Diego, CA (US); Raheel AZMAT, Cork (IE)

(21) Appl. No.: 18/732,964

(22) Filed: Jun. 4, 2024

(51) Int. Cl. H01L 27/118

(52) U.S. Cl. CPC H10D 84/907; H10D 84/912; H10D 84/914; H10D 84/975; H10D 84/981; H10D 84/988

(57) ABSTRACT

A chip includes a first row of cells including a first cell, and a second row of cells including a second cell, wherein the second row of cells is adjacent to the first row of cells. The chip also includes first tracks providing signal routing for the first cell, wherein each of the first tracks extends in a first direction, and one of the first tracks overlaps a boundary between the first cell and the second cell. The chip also includes second tracks providing signal routing for the second cell, wherein each of the second tracks extends in the first direction.

### BACKGROUND

### Field

Aspects of the present disclosure relate generally to chip layout, and more particularly, to track floorplans for cells on a chip.

### Background

A chip includes many transistors for performing various functions on the chip. The transistors may be implemented using fin field effect transistors (FinFETs), gate-all-around field effect transistors (GAAFETs), and/or other types of transistors. Transistors on the chip may be organized into cells. Each cell may include one or more transistors that are arranged to implement a circuit (e.g., an inverter, a driver, a logic gate, combinational logic, or another type of circuit). The chip may also include tracks in a metal layer to provide signal routing for the cells.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first row of cells including a first cell, and a second row of cells including a second cell, wherein the second row of cells is adjacent to the first row of cells. The chip also includes first tracks providing signal routing for the first cell, wherein each of the first tracks extends in a first direction, and one of the first tracks overlaps a boundary between the first cell and the second cell. The chip also includes second tracks providing signal routing for the second cell, wherein each of the second tracks extends in the first direction.

A second aspect relates to a chip. The chip includes a first row of cells including a first cell, and a second row of cells including a second cell, wherein the second row of cells is adjacent to the first row of cells. The chip also includes first tracks providing signal routing for the first cell, wherein each of the first tracks extends in a first direction, and one of the first tracks overlaps the second cell. The chip also includes second tracks providing signal routing for the second cell, wherein each of the second tracks extends in the first direction.

A third aspect relates to a chip. The chip includes a first row of cells including a first cell, and a second row of cells including a second cell, wherein the second row of cells is adjacent to the first row of cells. The chip also includes a first rail, a second rail, a third rail, and first tracks providing signal routing for the first cell, wherein each of the first tracks extends in a first direction, and the first tracks are disposed between the first rail and the second rail in a second direction perpendicular to the first direction. The chip also includes second tracks providing signal routing for the second cell, wherein each of the second tracks extends in the first direction, the second tracks are disposed between the second rail and the third rail in the second direction, and a number of the second tracks is greater than a number of the first tracks.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary layout of diffusion regions and gates in a cell according to certain aspects of the present disclosure.

FIG. 3 shows a top view of an exemplary M0 track floorplan for providing the cell with signal routing and power routing according to certain aspects of the present disclosure.

FIG. 4A shows an example of a M0 track plan for an example in which the cell implements an inverter according to certain aspects of the present disclosure.

FIG. 4B shows an example of a M0 track plan for an example in which the cell implements a NAND gate according to certain aspects of the present disclosure.

FIG. 4C shows an example of a M0 track plan for an example in which the cell implements an AND-OR-Invert (AOI) circuit according to certain aspects of the present disclosure.

FIG. 5 shows an example of a row of cells according to certain aspects of the present disclosure.

FIG. 6 shows an exemplary M0 track floorplan for two adjacent rows of cells according to certain aspects of the present disclosure.

FIG. 7 shows another exemplary M0 track floorplan for two adjacent rows of cells according to certain aspects of the present disclosure.

FIG. 8 shows an example of a M0 track floorplan with a nonuniform allocation of tracks between rows of cells according to certain aspects of the present disclosure.

FIG. 9 shows a side-by-side comparison between the M0 track floorplan of FIG. 6 and the M0 track floorplan of FIG. 8 according to certain aspects of the present disclosure.

FIG. 10A shows a cross-sectional view of cells in the two adjacent rows taken along a first cross-sectional line in FIG. 9 according to certain aspects of the present disclosure.

FIG. 10B shows a cross-sectional view of the cells in the two adjacent rows taken along a second cross-sectional line in FIG. 9 according to certain aspects of the present disclosure.

FIG. 11 shows an example of flexible placement of cells in the rows according to certain aspects of the present disclosure.

FIG. 12 shows another example of a M0 track floorplan with a nonuniform allocation of tracks between rows of cells according to certain aspects of the present disclosure.

FIG. 13 shows yet another example of a M0 track floorplan with a nonuniform allocation of tracks between rows of cells according to certain aspects of the present disclosure.

FIG. 14 shows still another example of a M0 track floorplan with a nonuniform allocation of tracks between rows of cells according to certain aspects of the present disclosure.

FIG. 15 shows a further example of a M0 track floorplan with a nonuniform allocation of tracks between rows of cells according to certain aspects of the present disclosure.

FIG. 16A shows an example of a M0 track floorplan with a nonuniform allocation of tracks between rows of cells and power rails according to certain aspects of the present disclosure.

FIG. 16B shows an example of diffusion regions in the rows of cells of FIG. 16A according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

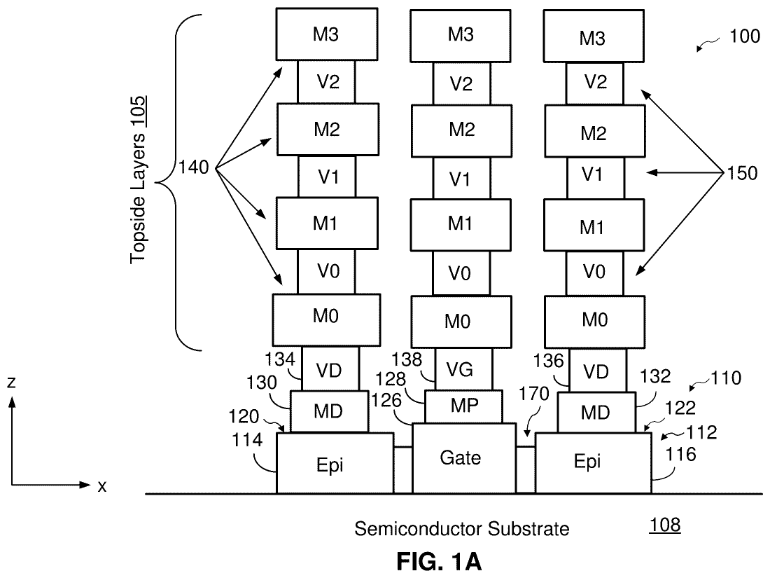

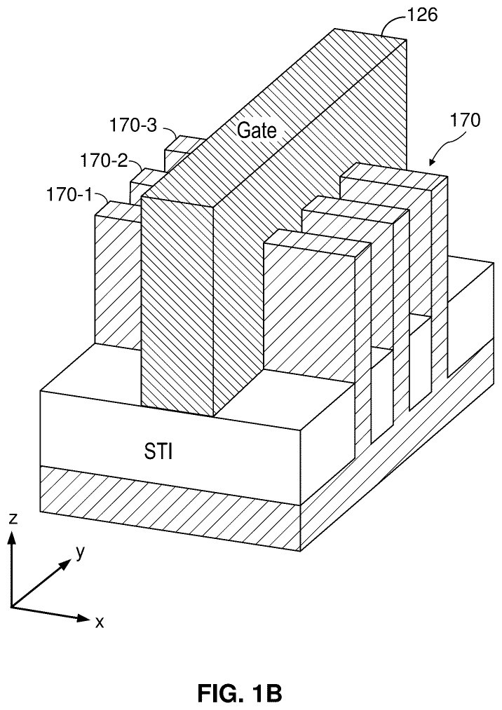

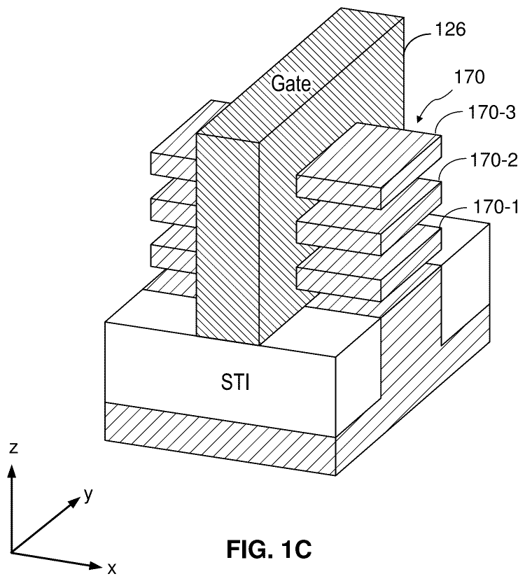

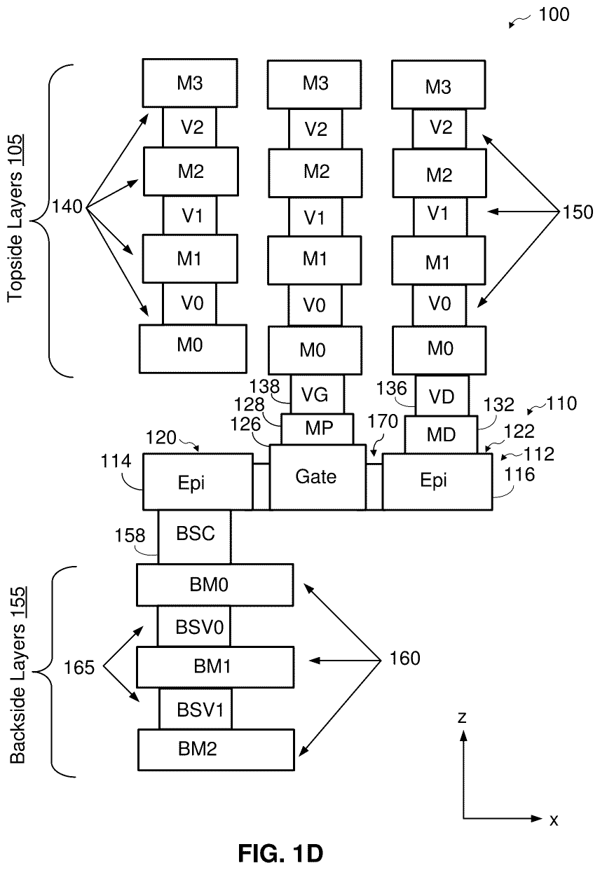

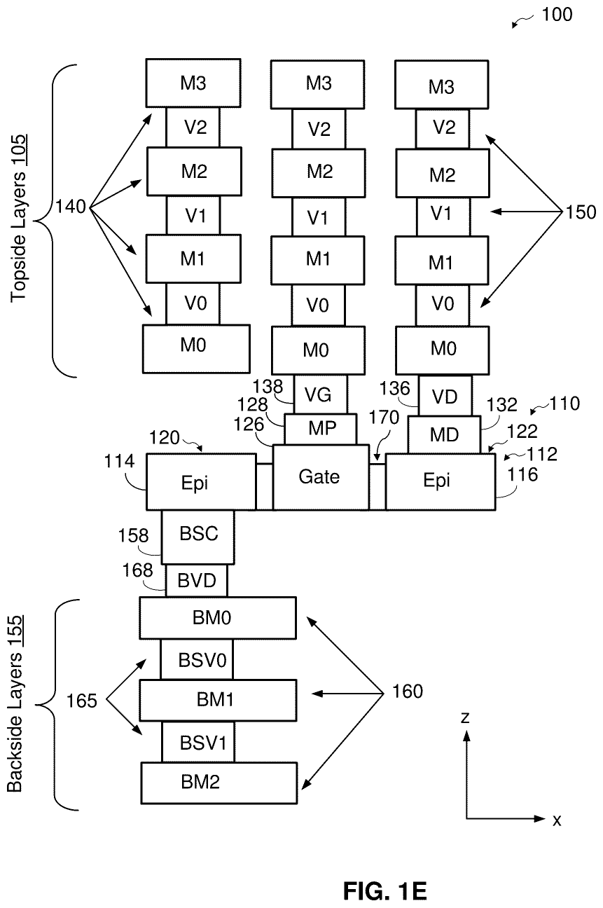

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between devices on the chip 100. In some implementations, the STI may be omitted.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and each of the first epi layer 114 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. In this example, the chip 100 also includes a via 134 disposed between the contact 130 and metal layer M0, in which the via 134 couples the contact 130 to metal layer M0. The chip 100 also includes a via 136 disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

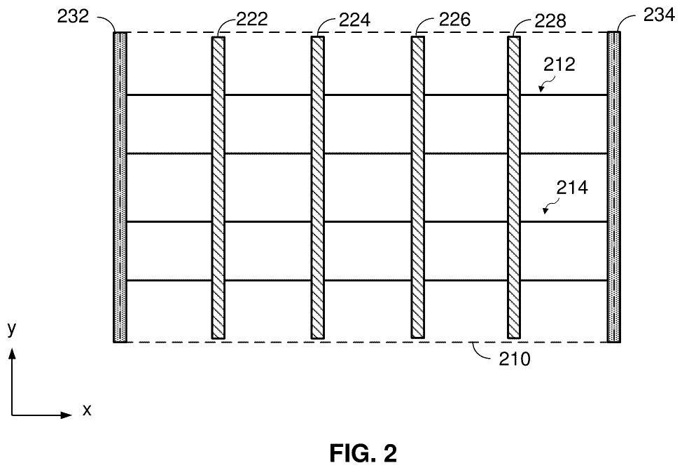

FIG. 2 shows a top view of an exemplary layout of diffusion regions and gates in a cell 210 (e.g., a standard cell) according to certain aspects of the present disclosure. In this example, the boundary of the cell 210 is indicated by the dashed line shown in FIG. 2.

In this example, the diffusion regions in the cell 210 include a first diffusion region 212 and a second diffusion region 214 extending in the x direction. The first diffusion region 212 may be a p-type diffusion region and the second diffusion region 214 may be an n-type diffusion region, or vice versa.

In this example, the gates in the cell 210 include gates 222, 224, 226, and 228 extending in the y direction. The gates 222, 224, 226, and 228 may be spaced apart in the x direction by a uniform pitch, as shown in the example in FIG. 2. Each of the gates 222, 224, 226, and 228 may include a metal (e.g., a high-k metal gate (HKMG)), polysilicon, and/or another gate material. It is to be appreciated that the cell 210 is not limited to the number of gates shown in the example in FIG. 2, and that the cell 210 may include a smaller number of gates or a larger number of gates (e.g., depending on the complexity of the circuit implemented by the cell 210).

In this example, the first diffusion region 212 may include one or more first channels extending in the x direction (e.g., an instance of the one or more channels 170), in which the one or more first channels pass through one or more of the gates 222, 224, 226, and 228. The second diffusion region 214 may include one or more second channels extending in the x direction (e.g., an instance of the one or more channels 170), in which the one or more second channels pass through one or more of the gates 222, 224, 226, and 228. Each channel may include a fin, a nanosheet, or another type of channel (e.g., depending on whether the diffusion regions 212 and 214 are fabricated using a FinFET process, a gate-all-around FET process, or another type of process). Each of the diffusion regions 212 and 214 may also include epi layers (e.g., instances of the epi layers 114 and 116).

FIG. 2 also shows an example of a first diffusion break 232 on the left boundary of the cell 210, and a second diffusion break 234 on the right boundary of the cell 210. The diffusion breaks 232 and 234 may be used to isolate the diffusion regions 212 and 214 from diffusion regions in adjacent cells (not shown in FIG. 2). Each of the diffusion breaks 232 and 234 may include a single diffusion break, a double diffusion break, or another type of diffusion break.

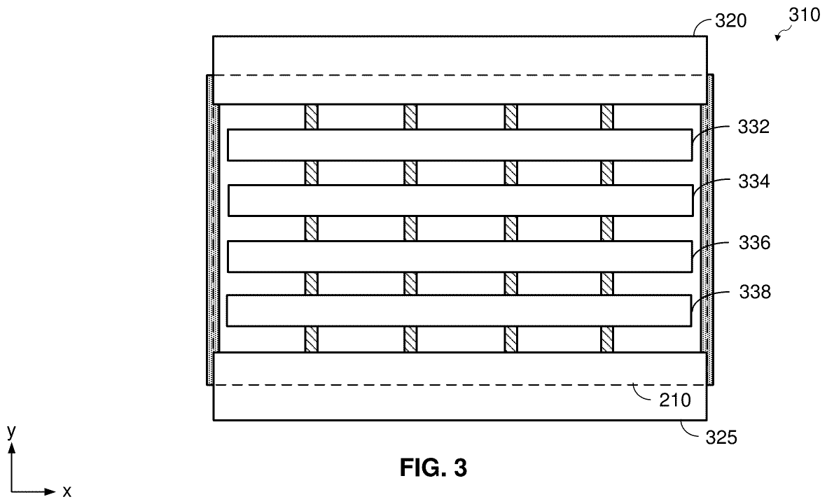

FIG. 3 shows a top view of an exemplary track floorplan 310 (i.e., track layout) in metal layer M0 over the cell 210. For ease of illustration, the diffusion regions 212 and 214 are not shown in FIG. 3.

In this example, the track floorplan 310 includes tracks 332, 334, 336, and 338 in metal layer M0 located between a first rail 320 and a second rail 325 in the y direction. The tracks 332, 334, 336, and 338 are used to provide signal routing for the cell 210. Each of the tracks 332, 334, 336, and 338 and each of the rails 320 and 325 extends in the x direction. The tracks 332, 334, 336, and 338 are spaced apart in the y direction (e.g., by a uniform pitch). A track may also be referred to as a wire or another term.

In the example shown in FIG. 3, the rails 320 and 325 in metal layer M0 provide frontside power routing for the cell 210. However, it is to be appreciated that the track floorplan 310 is not limited to this example. For example, in some implementations, power may be routed to the cell 210 using backside rails (not shown) formed in backside metal layer BM0 (shown in FIGS. 1D and 1E). For the example of backside power routing, the rails 320 and 325 in metal layer M0 may be omitted.

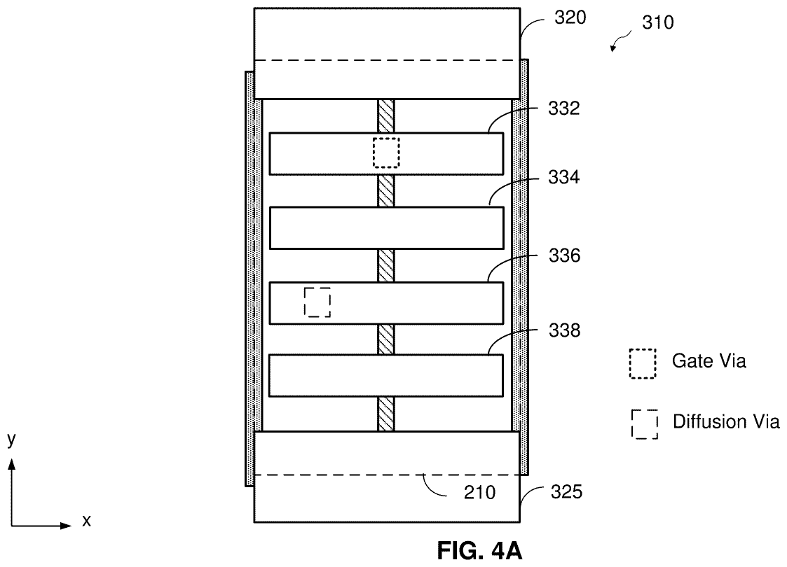

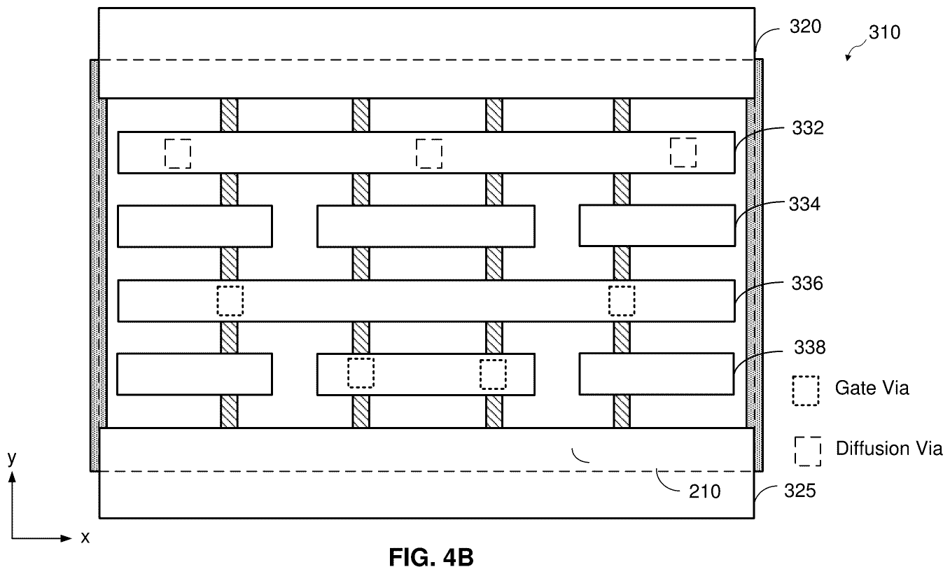

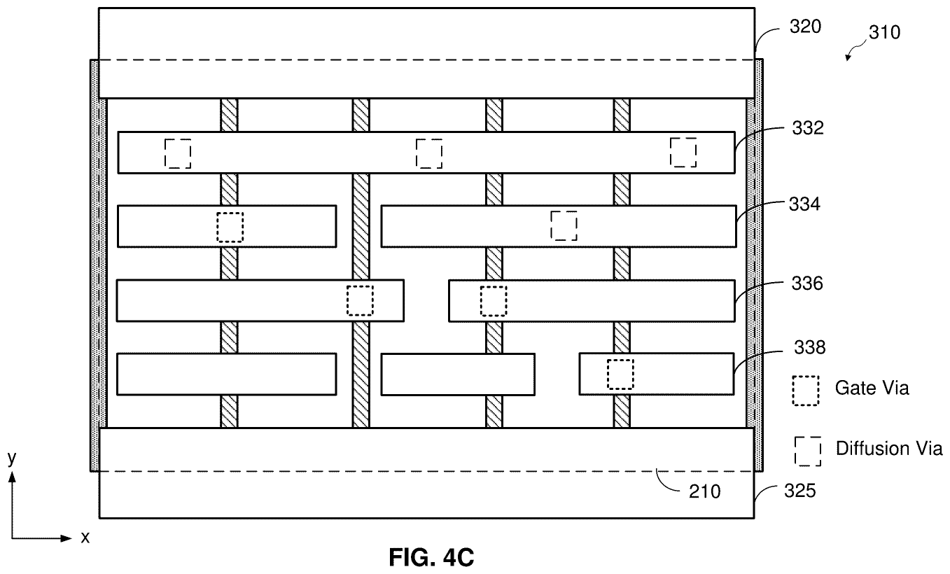

In the example shown in FIG. 3, the track floorplan 310 includes four tracks 332, 334, 336, and 338 for signal routing. The cell 210 may utilize all four tracks 332, 334, 336, and 338 for signal routing or less than all four tracks 332, 334, 336, and 338 for signal routing depending, for example, on the complexity of the circuit implemented by the cell 210. In this regard, FIGS. 4A, 4B, and 4C illustrate examples of track utilization for three types of circuits that may be implemented by the cell 210. As used herein, a “signal” may include a digital signal that changes logic states to represent data, a command, or other information. A signal does not include a supply voltage.

FIG. 4A shows an example of track utilization for an example in which the cell 210 implements an inverter. In this example, the cell 210 includes the gate 222 with the gates 224, 226, and 228 omitted. FIG. 4A shows an example of a gate via (shown in dotted line) and a diffusion via (shown in dashed line). Note that the gate via and the diffusion via are below the tracks 332, 334, 336, and 338, which are in metal layer M0.

In the example in FIG. 4A, the gate via couples the gate 222 to the track 332 to provide signal routing for the input of the inverter. The diffusion via is coupled to the track 336 and coupled to the diffusion regions 212 and 214 (shown in FIG. 2) to provide signal routing for the output of the inverter. The diffusion via may be coupled to the diffusion regions 212 and 214 through a contact (e.g., MD contact in FIG. 1A) extending over the diffusion regions 212 and 214 in the y direction. Note that the vias for coupling the rails 320 and 325 to the cell 210 are not shown in FIG. 4A, and the contact layer (e.g., MD layer in FIG. 1A) is not shown in FIG. 4A.

In this example, the cell 210 utilizes the tracks 332 and 336 and does not utilize the tracks 334 and 338. Thus, in this example, the cell 210 utilizes two of the four available tracks 332, 334, 336, and 338 in the track floorplan 310. In this example, the cell 210 may be referred to as a two-track (2T) cell. As used herein, a 2T cell is a cell utilizing two tracks for signal routing.

FIG. 4B shows an example of track utilization for an example in which the cell 210 implements a NAND gate. In this example, the cell 210 includes the gates 222, 224, 226, and 228. FIG. 4B shows an example of gate vias (shown in dotted line) and diffusion vias (shown in dashed line). Note that the gate vias and the diffusion vias are below the tracks 332, 334, 336, and 338, which are in metal layer M0.

In the example in FIG. 4B, the gate vias couple the gates 222 and 228 to the track 336 and couple the gates 224 and 226 to the track 338 to provide signal routing for the inputs of the NAND gate. The diffusion vias couple the first diffusion region 212 and/or the second diffusion region 214 (shown in FIG. 2) to the track 332 to provide signal routing for the output of the NAND gate. In this example, the tracks 334 and 338 are cut at the locations shown in FIG. 4B. Note that the vias for coupling the rails 320 and 325 to the cell 210 are not shown in FIG. 4B, and the contact layer (e.g., MD layer in FIG. 1A) is not shown in FIG. 4B.

In this example, the cell 210 utilizes the tracks 332, 336, and 338 and does not utilize the track 334. Thus, in this example, the cell 210 utilizes three of the four available tracks 332, 334, 336, and 338 in the track floorplan 310. In this example, the cell 210 may be referred to as a three-track (3T) cell. As used herein, a 3T cell is a cell utilizing three tracks for signal routing. Other examples of a 3T cell may include a cell implementing a NOR gate, or another type of logic gate.

FIG. 4C shows an example of track utilization for an example in which the cell 210 implements an AND-OR-Invert (AOI) circuit. In this example, the cell 210 includes the gates 222, 224, 226, and 228. FIG. 4C shows an example of gate vias (shown in dotted line) and diffusion vias (shown in dashed line). Note that the gate vias and the diffusion vias are below the tracks 332, 334, 336, and 338, which are in metal layer M0.

In the example in FIG. 4C, the gate vias couple the gate 222 to track 334, couple the gates 224 and 226 to the track 336, and couple the gate 228 to the track 338 to provide signal routing for the inputs of the AOI circuit. The diffusion vias couple the first diffusion region 212 and/or the second diffusion region 214 (shown in FIG. 2) to the tracks 332 and 334 to provide signal routing for the output of the AOI circuit. In this example, the tracks 334, 336, and 338 are cut at the locations shown in FIG. 4C. Note that the vias for coupling the rails 320 and 325 to the cell 210 are not shown in FIG. 4C, and the contact layer (e.g., MD layer in FIG. 1A) is not shown in FIG. 4C.

In the example in FIG. 4C, the cell 210 utilizes all four of the available tracks 332, 334, 336, and 338 in the track floorplan 310. In this example, the cell 210 may be referred to as a four-track (4T) cell. As used herein, a 4T cell is a cell utilizing four tracks for signal routing. Other examples of a 4T cell may include a multiplexer, an adder, combinational logic, and the like.

Thus, FIGS. 4A, 4B, and 4C illustrate examples in which the cell 210 uses two tracks, three tracks, or four tracks depending on the type of circuit implemented by the cell 210. In this regard, the standard cell library may include cells using two tracks (e.g., inverter), cells using three tracks (e.g., NAND gate, NOR gate, and other types of logic gates), and cells using four tracks (e.g., AOI circuit, a multiplexer, and other types of circuits). Thus, the track utilization (i.e., number of tracks used) may vary across the cells in the standard cell library.

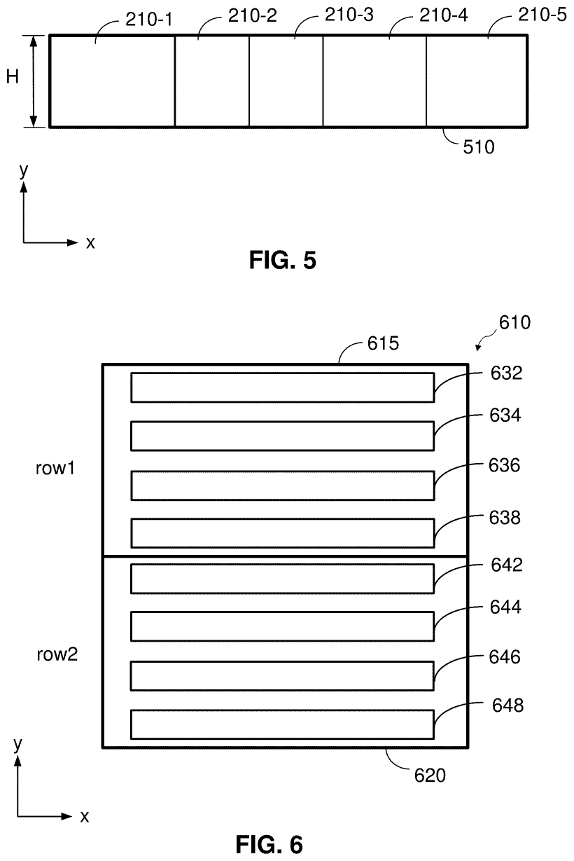

In certain aspects, cells may be arranged (i.e., laid out) in rows on the chip 100. In this regard, FIG. 5 illustrates an example of cells 210-1 to 210-5 arranged in a row 510 extending in the x direction. In this example, the cells 210-1 to 210-5 may have the same height H in the y direction, as shown in FIG. 5. The cells 210-1 to 210-5 may have the same width in the x direction or varying widths in the x direction (e.g., based on the number of gates in each cell). The cells 210-1 to 210-5 may include 2T cells, 3T cells, 4T cells, or any combination thereof. It is to be appreciated that the row 510 may include additional cells not shown in FIG. 5.

FIG. 6 shows an exemplary track floorplan 610 for two adjacent rows of cells according to certain aspects of the present disclosure. The two adjacent rows include a first row 615 (labeled “row1”) and a second row 620 (labeled “row2”). As used herein, two rows of cells are adjacent to each other when there is no intervening cell between the two rows of cells. In the example in FIG. 6, the rows 615 and 620 have equal heights in the y direction. It is to be appreciated that the rows 615 and 620 may extend farther in the x direction than shown in FIG. 6. For ease of illustration, the individual cells in each row are not shown in FIG. 6.

In this example, the floorplan 610 includes tracks 632, 634, 636, and 638 for providing signal routing for cells in the first row 615, and tracks 642, 644, 646, and 648 for providing signal routing for cells in the second row 620. It is to be appreciated that each of the tracks may be cut at various locations (not shown) to provide signal paths for individual inputs and/or outputs. Each of the tracks 632, 634, 636, 638, 642, 644, 646, and 648 extends in the x direction and are spaced apart from one another in the y direction.

Note that the rails for the rows 615 and 620 are not shown in FIG. 6. The rails may be formed in backside metal layer BMO for backside power distribution or formed in metal layer M0 for frontside power distribution.

In this example, the floorplan 610 includes four tracks (i.e., wires) for each of the rows 615 and 620. A drawback of the floorplan 610 shown in FIG. 6 is that the floorplan leads to area inefficiencies when the rows 615 and 620 include 2T cells and 3T cells (i.e., cells using two tracks and cells using three tracks). This is because the floorplan 610 includes four tracks for each row 615 and 620 to accommodate 4T cells, which results in wasted area for cells that do not need four tracks.

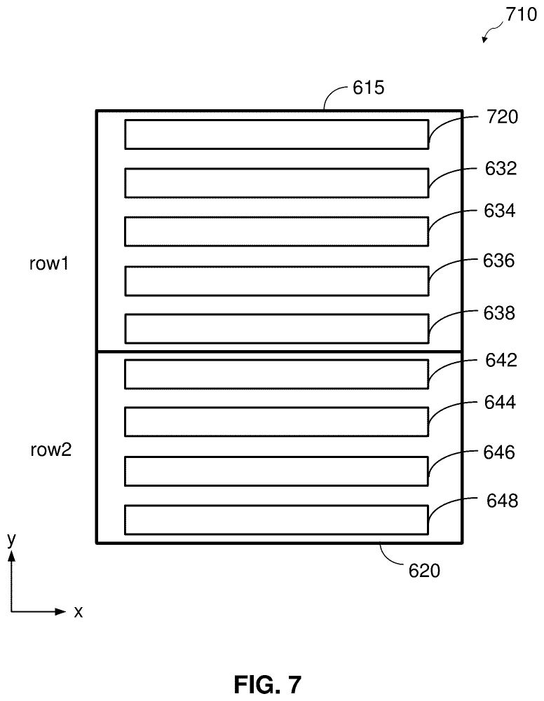

FIG. 7 shows another example of a track floorplan 710 according to certain aspects. The floorplan 710 includes the tracks 632, 634, 636, 638, 642, 644, 646, and 648 discussed above with reference to FIG. 6. The floorplan 710 also includes an additional track 720 for the first row 615. Thus, in this example, the floorplan 710 includes five tracks for the first row 615 and four tracks for the second row 620 for an average of 4.5 tracks per row.

In this example, the first row 615 is used to accommodate stronger cells than the cells in the second row 620. The stronger cells have wider diffusion regions (not shown in FIG. 7) than the cells in the second row 620 to increase the drive strengths of the stronger cells. As a result, the stronger cells in the first row 615 have a larger height than the cells in the second row 620. In this example, the stronger cells in the first row 615 may be used for higher performance while the cells in the second row 620 may be used for lower power applications. The cells in the second row 620 may also be referred to as weaker cells.

Thus, the exemplary floorplan 710 accommodates stronger cells in the first row 615 for high performance and weaker cells in the second row 620 for low power. However, a drawback of the floorplan 710 is that the floorplan 710 may lead to area inefficiencies when the distribution of stronger cells and weaker cells is not even. For example, for cases where a circuit block in the chip 100 includes a larger number of weaker cells than stronger cells for lower power, the first row 615 may have a large number of empty spaces resulting in wasted space. For cases where a circuit block in the chip 100 includes a larger number of stronger cells than weaker cells for higher performance, the second row 620 may have a large number of empty spaces resulting in wasted space. In short, the floorplan 710 places a rigid restriction on the placement of stronger cells and weaker cells that leads to area inefficiencies when the distribution of stronger cells and weaker cells is not 50/50.

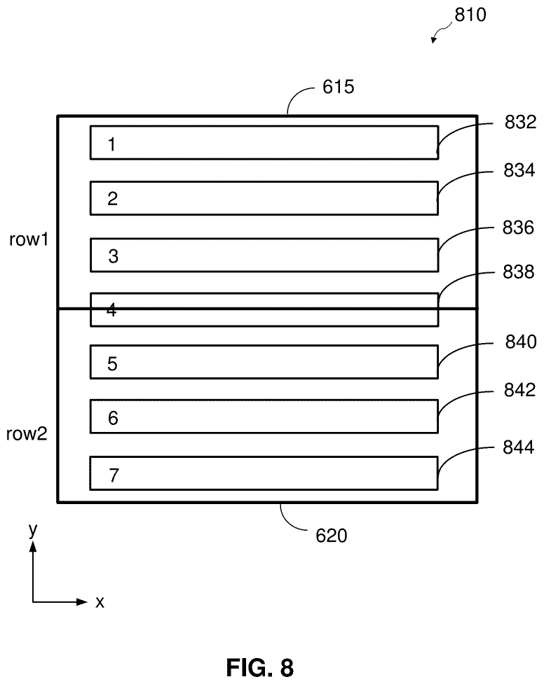

FIG. 8 shows an exemplary track floorplan 810 according to certain aspects of the present disclosure. The track floorplan 810 may provide improved area efficiency for circuit blocks including 3T cells and 4T cells, as discussed further below.

In this example, the rows 615 and 620 have equal heights in the y direction. For example, the cells in the first row 615 and the cells in the second row 620 may have equal diffusion region widths in the y direction. Thus, in this example, the cells in the first row 615 and the cells in the second row 630 may have equal strengths.

In the example shown in FIG. 8, the floorplan 810 includes tracks 832, 834, 836, 838, 840, 842, and 844 in metal layer M0, in which the tracks are arranged in parallel. In this example, the tracks 832, 834, 836, 838, 840, 842, and 844 extend in the x direction and are spaced apart from one another in the y direction (e.g., by a uniform pitch). The tracks 832, 834, 836, 838, 840, 842, and 844 are spread across the first row 615 and the second row 620 with the track 838 overlapping the boundary between the first row 615 and the second row 620. As used herein, a “track” is elongated and extends in the lengthwise direction.

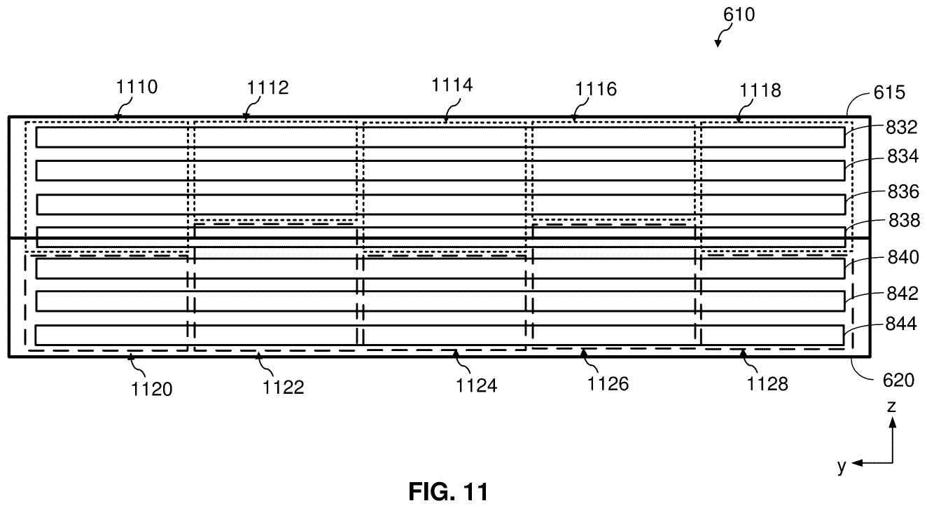

In one example, the tracks 832, 834, 836, and 838 may be allocated for the cells in the first row 615, and the tracks 840, 842, and 844 may be allocated for the cells in the second row 620. The tracks 832, 834, 836, and 838 may also be referred to as first tracks and the tracks 840, 842, and 844 may also be referred to as second tracks. Thus, in this example, four tracks (i.e., tracks 832, 834, 836, and 838) are allocated for the cells in the first row 615 and three tracks (i.e., tracks 840, 842, and 844) are allocated for the cells in the second row 620. In this example, the first row 615 may be used for placement of cells using four tracks (i.e., 4T cells) and the second row 620 may be used for placement of cells using three tracks (i.e., 3T cells) or less (e.g., 2T cells). However, it is to be appreciated that the present disclosure is not limited to this example. In certain aspects, the floorplan 810 allows flexible placement of 4T cells and 3T cells in the rows 615 and 620, as discussed further below with reference to FIG. 11. The floorplan 810 provides high area efficiency, for example, for a circuit block including an even distribution of 4T cells and 3T cells.

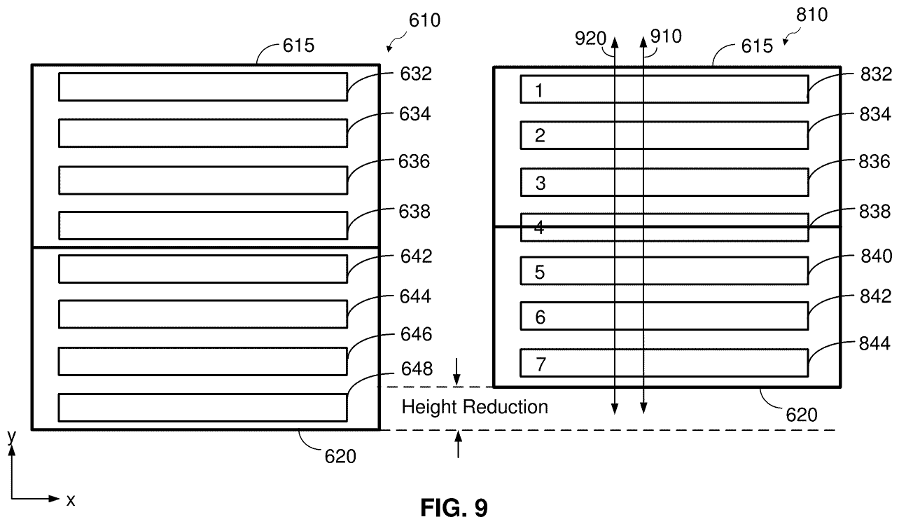

The average number of tracks per row is 3.5 (i.e., 3.5T) in this example. This results in a height reduction (and hence area reduction) compared with the exemplary floorplan 610 shown in FIGS. 6, which includes four tracks per row. An example of the height reduction is illustrated in FIG. 9, which shows a side-by-side comparison of the floorplan 610 and the floorplan 810. As shown in FIG. 9, the floorplan 810 reduces the height of the rows 615 and 620 (and hence the cells) compared with the floorplan 610 in FIG. 6, which allocates four tracks per row.

For the example where the cells in the first row 615 and the cells in the second row 620 have equal diffusion region widths, the floorplan 810 does not impose placement restrictions on the cells based on diffusion region widths in contrast to the floorplan 710 shown in FIG. 7.

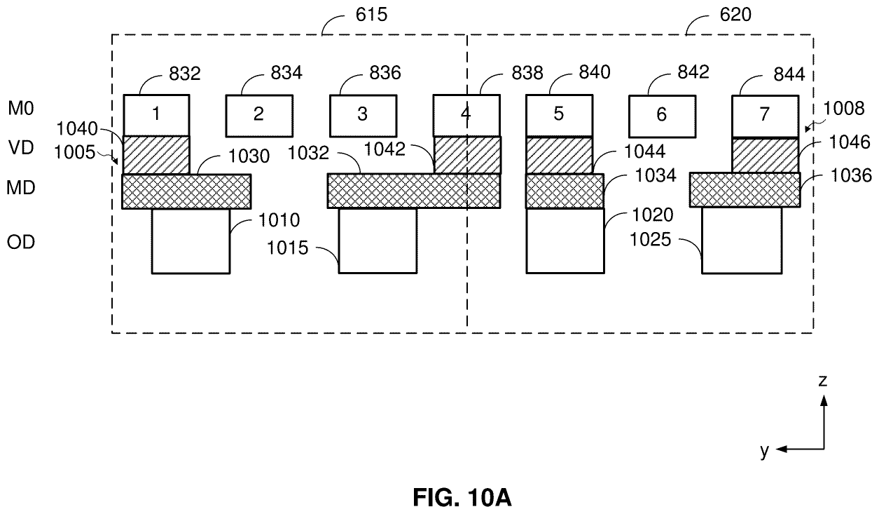

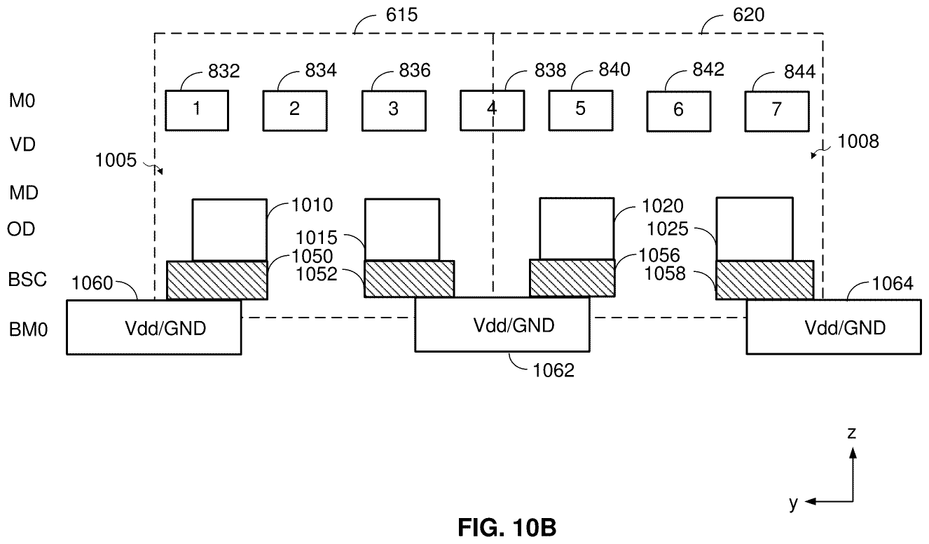

FIG. 10A shows an example of a cross-sectional view of a cell 1005 in the first row 615 and a cell 1008 in the second row 620 taken along the cross-sectional line 910 in FIG. 9. In FIG. 10A, the boundaries of the rows 615 and 620 are shown in dashed line. In this example, the track 838 is placed at the boundary between the rows 615 and 620.

In this example, the cell 1005 in the first row 615 includes diffusion regions 1010 and 1015 extending in the x direction and spaced apart in the y direction. The cell 1008 in the second row 620 includes diffusion regions 1020 and 1025 extending in the x direction and spaced apart in the y direction. In this example, the diffusion regions 1010 and 1015 in the cell 1005 and the diffusion regions 1020 and 1025 in the cell 1008 have equal widths in the y direction (i.e., the widths of the diffusion regions 1010, 1015, 1020, and 1025 are uniform).

In this example, the diffusion region 1010 is coupled to the track 832 through a contact 1030 disposed on the diffusion region 1010, and a via 1040 disposed between the contact 1030 and the track 832. The diffusion region 1015 is coupled to the track 838 through a contact 1032 disposed on the diffusion region 1015, and a via 1042 disposed between the contact 1032 and the track 838. In this example, the contact 1032 extends under the track 838 to allow the via 1042 to couple the contact 1032 to the track 838. Thus, in this example, the track 838 lying on the boundary between the cells 1005 and 1008 is used by the cell 1005 for signal routing (i.e., the track 838 is stolen by the cell 1005 in this example).

In this example, the diffusion region 1020 is coupled to the track 840 through a contact 1034 disposed on the diffusion region 1020, and a via 1044 disposed between the contact 1034 and the track 840. The diffusion region 1025 is coupled to the track 844 through a contact 1036 disposed on the diffusion region 1025, and a via 1046 disposed between the contact 1036 and the track 844.

FIG. 10B shows another cross-sectional view of the cell 1005 in the first row 615 and the cell 1008 in the second row 620 taken along the cross-sectional line 920 in FIG. 9. In this example, power is routed to the cells 1005 and 1008 through a backside power distribution network including a first rail 1060, a second rail 1062, and a third rail 1064 in backside metal layer BMO. The first rail 1060 and the third rail 1064 may be supply rails and the second rail 1062 may be a ground rail, or vice versa. In this example, the diffusion region 1010 is coupled to the first rail 1060 through backside contact 1050, and the diffusion region 1015 is coupled to the second rail 1062 through backside contact 1052. Also, the diffusion region 1020 is coupled to the second rail 1062 through backside contact 1056, and the diffusion region 1025 is coupled to the third rail 1064 through backside contact 1058.

In one example, 4T cells may be placed in the first row 615 and 3T cells may be placed in the second row 620, in which the tracks 832, 834, 836, and 838 in the floorplan 610 are allocated for the 4T cells in the first row 615 and the tracks 840, 842, and 844 in the floorplan 610 are allocated for the 3T cells in the second row 620. However, the floorplan 610 is not limited to this example. In other examples, the allocation of the tracks 832, 834, 836, 838, 840, 842, and 844 between the first row 615 and the second row 620 may be flexibility allowing for flexible placement of 4T cells and 3T cells in the rows 615 and 620.

In this regard, FIG. 11 shows an example of flexible allocation of the tracks 832, 834, 836, 838, 840, 842, and 844 between the first row 615 and the second row 620 according to certain aspects. In FIG. 11, the allocation of the tracks for the first row 615 are shown in dotted line and the allocation of the tracks for the second row 620 are shown in dashed line. In the example in FIG. 11, four tracks are allocated to portions 1110, 1114, and 1118 of the first row 615 and three tracks are allocated to portions 1112 and 1116 of the first row 615. Also, three tracks are allocated to portions 1120, 1124, and 1128 of the second row 620 and four tracks are allocated to portions 1122 and 1126 of the second row 620. Each portion of a row may include one or more cells including one or more filler cells. A portion of a row may also be referred to as a region or another term.

In the example shown in FIG. 11, 4T cells may be placed in portions 1110, 1114, and 1118 of the first row 615 and portions 1122 and 1126 of the second row 620. The sizes and locations of these portions of the first row 615 and the second row 620 may vary depending, for example, on a desired placement of 4T cells. Thus, the floorplan 610 supports flexible placement of 4T cells in the first row 615 and the second row 620.

In the example shown in FIG. 11, 3T cells may be placed in portions 1112 and 1116 of the first row 615 and portions 1120, 1124, and 1128 of the second row 620. The sizes and locations of these portions of the first row 615 and the second row 620 may vary depending, for example, on a desired placement of 3T cells. Thus, the floorplan 610 supports flexible placement of 3T cells in the first row 615 and the second row 620.

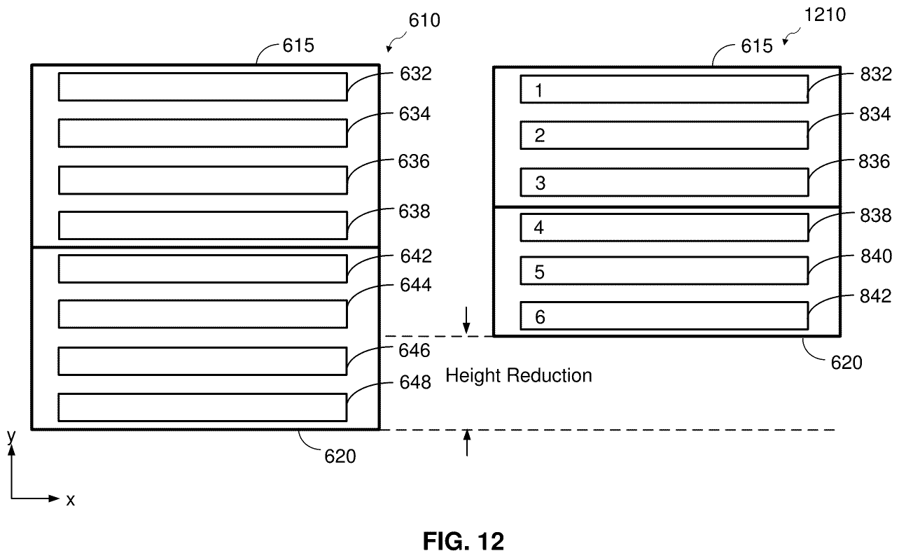

FIG. 12 shows another exemplary track floorplan 1210 according to certain aspects of the present disclosure. The track floorplan 1210 may provide improved area efficiency for circuit blocks including 4T cells and 2T cells, as discussed further below.

In this example, the rows 615 and 620 have equal heights in the y direction. For example, the cells in the first row 615 and the cells in the second row 620 may have equal diffusion region widths in the y direction.

In the example shown in FIG. 12, the floorplan 1210 includes the tracks 832, 834, 836, 838, 840, and 842 with the track 844 omitted. Thus, the floorplan 1210 includes six tracks spread across the first and second rows 615 and 620. In this example, the tracks 832, 834, 836, and 838 may be allocated for the cells in the first row 615 and the tracks 840 and 842 may be allocated for the cells in the second row 620. In this example, the tracks 832, 834, 836, and 838 may also be referred to as first tracks and the tracks 840 and 842 may also be referred to as second tracks. In this example, the first row 615 may be used for placement of 4T cells and the second row 620 may be used for placement of 2T cells (i.e., inverter cells, buffer cells, and the like). However, it is to be appreciated that the present disclosure is not limited to this example. In certain aspects, the floorplan 1210 allows flexible placement of 4T cells and 2T cells in the rows 615 and 620 (e.g., in a manner similar to the flexible placement of 4T cells and 3T cells shown in FIG. 11).

Thus, the average number of tracks per row is 3 (i.e., 3T) in this example. This results in a height reduction (and hence area reduction) compared with the exemplary floorplan 610 shown in FIG. 6, which includes four tracks per row. An example of the height reduction is illustrated in FIG. 12, which shows a side-by-side comparison of the floorplan 610 and the floorplan 1210.

For the example where the cells in the first row 615 and the cells in the second row 620 have equal diffusion region widths, the floorplan 1210 does not impose placement restrictions on the cells based on diffusion region widths in contrast to the floorplan 710 in FIG. 7.

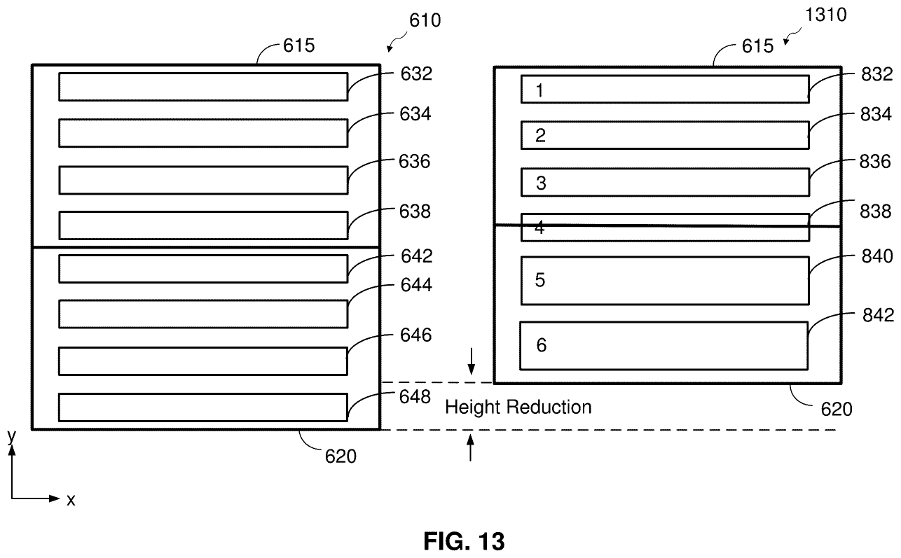

FIG. 13 shows another exemplary track floorplan 1310 according to certain aspects of the present disclosure. The track floorplan 1310 includes the tracks 832, 834, 836, 838, 840, and 842 in which the widths of the tracks 840 and 842 allocated to the 2T cells are widened in the y direction compared with the widths of the tracks 840 and 842 shown in FIG. 12. In this example, the wider widths of the tracks 840 and 842 provide lower resistance for the 2T cells, which may include inverters and buffers. The lower resistance improves the performance of the inverters and buffers, which may draw higher currents than other circuits on the chip 100.

Even with the tracks 840 and 842 being wider in this example, the floorplan 1310 still provides a height reduction (and hence area reduction) compared with the exemplary floorplan 610 shown in FIG. 6. An example of the height reduction is illustrated in FIG. 13, which shows a side-by-side comparison of the floorplan 610 and the floorplan 1310.

The exemplary floorplan 810 facilitates flexible allocation of tracks for 4T cells and 3T cells, and the exemplary floorplans 1210 and 1310 facilitate flexible allocation of tracks for 4T cells and 2T cells. However, it is to be appreciated that the present disclosure is not limited to these examples. The present disclosure may be expanded to provide floorplans to facilitate the flexible allocation of tracks for five-track (5T) cells and 4T/3T/2T cells, floorplans to facilitate the flexible allocation of tracks for six-track (6T) cells and 5T/4T/3T/2T cells, and so forth.

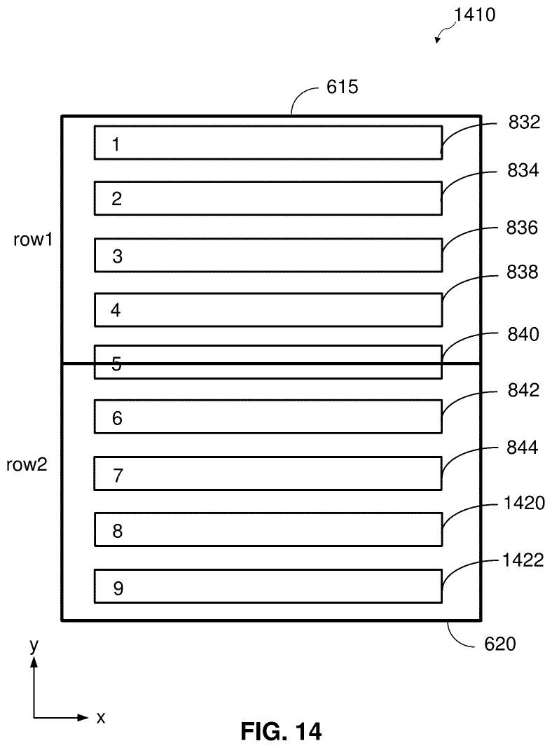

In this regard, FIG. 14 shows an exemplary track floorplan 1410 that provides improved area efficiency for circuit blocks including 5T cells and 4T cells according to certain aspects. In this example, the floorplan 1410 includes the tracks 832, 834, 836, 838, 840, 842, and 844 in metal layer M0. The floorplan 1410 also includes additional tracks 1420 and 1422 in metal layer M0, in which the tracks 832, 834, 836, 838, 840, 842, 844, 1420, and 1422 extend in the x direction and are spaced apart from one another in the y direction (e.g., by a uniform pitch). The tracks 832, 834, 836, 838, 840, 842, 844, 1420, and 1422 are spread across the first row 615 and the second row 620 with the track 840 overlapping the boundary between the first row 615 and the second row 620.

In this example, the rows 615 and 620 have equal heights in the y direction. For example, the cells in the first row 615 and the cells in the second row 620 may have equal diffusion region widths in the y direction.

In one example, the tracks 832, 834, 836, 838, and 840 may be allocated for the cells in the first row 615, and the tracks 842, 844, 1420 and 1422 may be allocated for the cells in the second row 620. The tracks 832, 834, 836, 838, and 840 may also be referred to as first tracks and the tracks 842, 844, 1420, and 1442 may also be referred to as second tracks. Thus, in this example, five tracks (i.e., tracks 832, 834, 836, 838, and 840) are allocated for the cells in the first row 615 and four tracks (i.e., tracks 842, 844, 1420, and 1422) are allocated for the cells in the second row 620. In this example, the first row 615 may be used for placement of 5T cells (i.e., cells utilizing five tracks) and the second row 620 may be used for placement 4T cells or cells utilizing fewer than four tracks. However, it is to be appreciated that the present disclosure is not limited to this example. In certain aspects, the floorplan 1410 allows flexible placement of 5T cells and 4T cells in the rows 615 and 620 (e.g., in a manner similar to the flexible placement of 4T cells and 3T cells shown in FIG. 11).

For the example where the cells in the first row 615 and the cells in the second row 620 have equal diffusion region widths, the floorplan 1410 does not impose placement restrictions on the cells based on diffusion region widths in contrast to the floorplan 710 shown in FIG. 7.

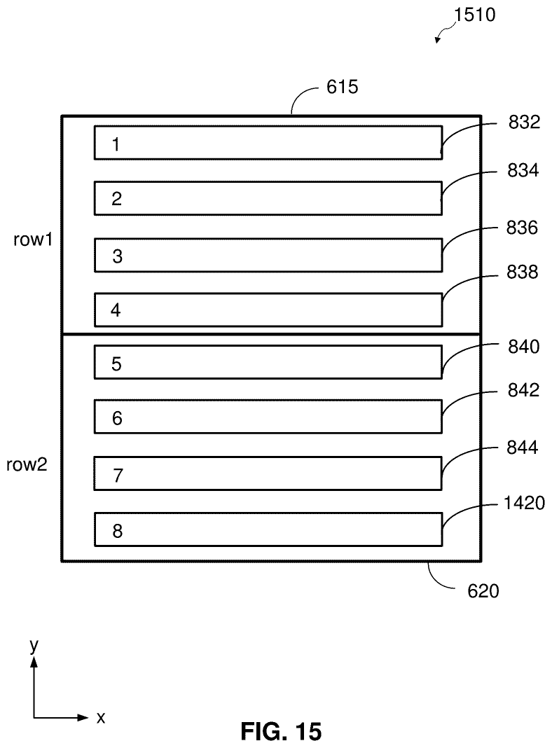

FIG. 15 shows another exemplary track floorplan 1510 according to certain aspects of the present disclosure. The track floorplan 1510 may provide improved area efficiency for circuit blocks including 5T cells and 3T cells, as discussed further below.

In this example, the rows 615 and 620 have equal heights in the y direction. For example, the cells in the first row 615 and the cells in the second row 620 may have equal diffusion region widths in the y direction.

In the example shown in FIG. 15, the floorplan 1510 includes the tracks 832, 834, 836, 838, 840, 842, 844, and 1420 with the track 1422 omitted. Thus, the floorplan 1510 includes eight tracks spread across the first and second rows 615 and 620. In this example, the tracks 832, 834, 836, 838, and 840 may be allocated for the cells in the first row 615 and the tracks 842, 844, and 1420 may be allocated for the cells in the second row 620. In this example, the tracks 832, 834, 836, 838, and 840 may also be referred to as first tracks and the tracks 842, 844, and 1420 may also be referred to as second tracks. In this example, the first row 615 may be used for placement of 5T cells and the second row 620 may be used for placement of 3T cells. However, it is to be appreciated that the present disclosure is not limited to this example. In certain aspects, the floorplan 1510 allows flexible placement of 5T cells and 3T cells in the rows 615 and 620 (e.g., in a manner similar to the flexible placement of 4T cells and 3T cells shown in FIG. 11).

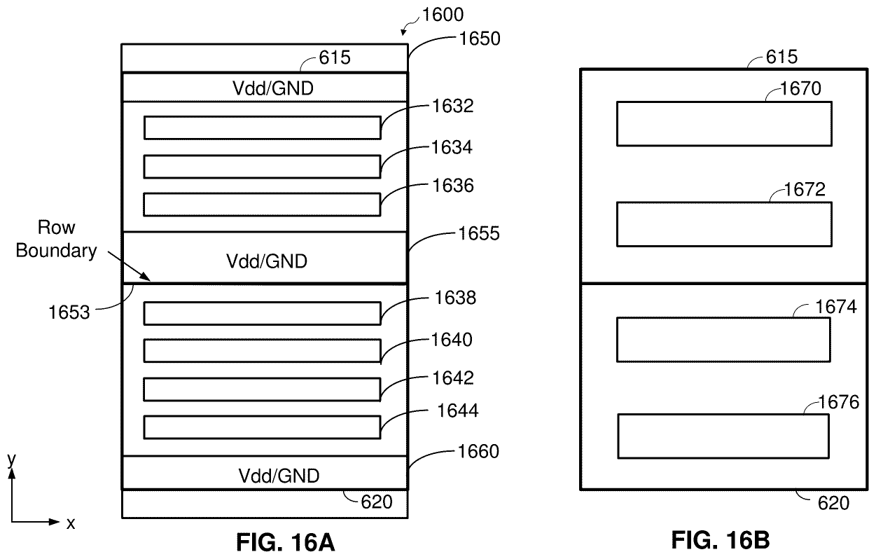

FIG. 16A shows another exemplary track floorplan 1610 according to certain aspects of the present disclosure. The track floorplan 1610 may provide improved area efficiency for circuit blocks including 3T cells and 4T cells, as discussed further below.

In this example, power is routed to the cells in the rows 615 and 620 using frontside power distribution. In this regard, FIG. 16A shows an example of a first rail 1650, a second rail 1655, and a third rail 1660 on the frontside. The first rail 1650 and the third rail 1660 may be supply rails and the second rail 1655 may be a ground rail, or vice versa. In the example shown in FIG. 16A, the second rail 1655 lies within the first row 615, in which the boundary between the rows is aligned with an edge 1653 of the second rail 1655. The boundary between the rows 615 and 620 is indicated in FIG. 16A. The second rail 1655 may be shared by cells in the first row 615 and cells in the second row 620.

In this example, the floorplan 1610 includes tracks 1632, 1634, and 1636 between the rails 1650 and 1655 in the y direction, and tracks 1638, 1640, 1642, and 1644 between the rails 1655 and 1660 in the y direction. Thus, in this example, three tracks (i.e., the tracks 1632, 1634, and 1636) are allocated for cells in the first row 615, and four tracks (e.g., the tracks 1638, 1640, 1642, and 1644) are allocated for cells in the second row 620. In this example, the first row 615 may be used for placement of 3T cells and the second row 620 may be used for placement of 4T cells. However, it is to be appreciated that the present disclosure is not limited to this example. In this example, the average number of tracks per row is 3.5 (i.e., 3.5T).

In this example, the height of the cells in the first row 615 and the height of the cells in the second row 620 are equal in the y direction. The cells in the first row 615 and the cells in the second row 620 may also have equal diffusion region widths in the y direction. In this regard, FIG. 16B shows an example in which the first row 615 includes the diffusion regions 1670 and 1672, and the second row 620 includes the diffusion region 1674 and 1676. Note that the tracks and rails are not shown in FIG. 16B. In this example, the widths of the diffusion regions 1670 and 1672 and the widths of the diffusion regions 1674 and 1674 are equal in the y direction.

Implementation examples are described in the following numbered clauses:
1. A chip, comprising:
   a first row of cells including a first cell;
   a second row of cells including a second cell, wherein the second row of cells is adjacent to the first row of cells;
   first tracks providing signal routing for the first cell, wherein each of the first tracks extends in a first direction, and one of the first tracks overlaps a boundary between the first cell and the second cell; and
   second tracks providing signal routing for the second cell, wherein each of the second tracks extends in the first direction.
2. The chip of clause 1, wherein a number of the first tracks is greater than a number of the second tracks.
3. The chip of clause 1 or 2, wherein the first cell comprises a four-track (4T) cell and the second cell comprises a three-track (3T) cell.
4. The chip of clause 1 or 2, wherein the first cell comprises a five-track (5T) cell and the second cell comprises a four-track (4T) cell.
5. The chip of any one of clauses 1 to 4, wherein:
   the first cell comprises a first diffusion region extending in the first direction; and
   the second cell comprises a second diffusion region extending in the first direction, wherein the first diffusion region and the second diffusion region have equal widths in a second direction perpendicular to the first direction.
6. The chip of clause 5, further comprising:
   a contact disposed on the first diffusion region, wherein the contact extends under the one of the first tracks; and
   a via disposed between the contact and the one of the first tracks.
7. The chip of any one of clauses 1 to 6, wherein the first tracks and the second tracks are in a metal layer above the first cell and the second cell.
8. The chip of any one of clauses 1, 2, and 5 to 7, wherein the first cell comprises a four-track (4T) cell and the second cell comprises a two-track (2T) cell.
9. The chip of clause 8, wherein each of the second tracks has a wider width in a second direction than each of the first tracks, and the second direction is perpendicular to the first direction.
10. The chip of clause 9, wherein:
   the first cell comprises a first diffusion region extending in the first direction; and
   the second cell comprises a second diffusion region extending in the first direction, wherein the first diffusion region and the second diffusion region have equal widths in the second direction.
11. The chip of any one of clauses 1 to 3, and 5 to 7, wherein:
   the first row of cells comprises a third cell;
   the second row of cells comprises a fourth cell;
   the first cell comprises a first four-track (4T) cell;
   the second cell comprises a first three-track (3T) cell;
   the third cell comprises a second 3T cell; and
   the fourth cell comprises a second 4T cell.
12. The chip of clause 11, wherein the second tracks and the one of the first tracks provide signal routing for the second 4T cell.
13. The chip of clause 12, wherein three of the first tracks provide signal routing for the second 3T cell.
14. A chip, comprising:
   a first row of cells including a first cell;
   a second row of cells including a second cell, wherein the second row of cells is adjacent to the first row of cells;
   first tracks providing signal routing for the first cell, wherein each of the first tracks extends in a first direction, and one of the first tracks overlaps the second cell; and
   second tracks providing signal routing for the second cell, wherein each of the second tracks extends in the first direction.
15. The chip of clause 14, wherein a number of the first tracks is greater than a number of the second tracks.
16. The chip of clause 14 or 15, wherein the first cell comprises a four-track (4T) cell and the second cell comprises a two-track (2T) cell.
17. The chip of clause 14 or 15, wherein the first cell comprises a five-track (5T) cell and the second cell comprises a three-track (3T) cell.
18. A chip, comprising:
   a first row of cells including a first cell;
   a second row of cells including a second cell, wherein the second row of cells is adjacent to the first row of cells;
   a first rail;
   a second rail;
   a third rail;
   first tracks providing signal routing for the first cell, wherein each of the first tracks extends in a first direction, and the first tracks are disposed between the first rail and the second rail in a second direction perpendicular to the first direction; and
   second tracks providing signal routing for the second cell, wherein each of the second tracks extends in the first direction, the second tracks are disposed between the second rail and the third rail in the second direction, and a number of the second tracks is greater than a number of the first tracks.
19. The chip of clause 18, wherein the first cell comprises a three-track (3T) cell and the second cell comprises a four-track (4T) cell.
20. The chip of clause 18 or 19, wherein:
   the first cell comprises a first diffusion region extending in the first direction; and
   the second cell comprises a second diffusion region extending in the first direction, wherein the first diffusion region and the second diffusion region have equal widths in the second direction.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. It is to be appreciated that the x direction, y direction, and z direction may also be referred to using numerical designations.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first row of cells including a first cell;
a second row of cells including a second cell, wherein the second row of cells is adjacent to the first row of cells;
first tracks providing signal routing for the first cell, wherein each of the first tracks extends in a first direction, and one of the first tracks overlaps a boundary between the first cell and the second cell; and
second tracks providing signal routing for the second cell, wherein each of the second tracks extends in the first direction.

2. The chip of claim 1, wherein a number of the first tracks is greater than a number of the second tracks.

3. The chip of claim 1, wherein the first cell comprises a four-track (4T) cell and the second cell comprises a three-track (3T) cell.

4. The chip of claim 1, wherein the first cell comprises a five-track (5T) cell and the second cell comprises a four-track (4T) cell.

5. The chip of claim 1, wherein:
the first cell comprises a first diffusion region extending in the first direction; and
the second cell comprises a second diffusion region extending in the first direction, wherein the first diffusion region and the second diffusion region have equal widths in a second direction perpendicular to the first direction.

6. The chip of claim 5, further comprising:
a contact disposed on the first diffusion region, wherein the contact extends under the one of the first tracks; and
a via disposed between the contact and the one of the first tracks.

7. The chip of claim 1, wherein the first tracks and the second tracks are in a metal layer above the first cell and the second cell.

8. The chip of claim 1, wherein the first cell comprises a four-track (4T) cell and the second cell comprises a two-track (2T) cell.

9. The chip of claim 8, wherein each of the second tracks has a wider width in a second direction than each of the first tracks, and the second direction is perpendicular to the first direction.

10. The chip of claim 9, wherein:
the first cell comprises a first diffusion region extending in the first direction; and
the second cell comprises a second diffusion region extending in the first direction, wherein the first diffusion region and the second diffusion region have equal widths in the second direction.

11. The chip of claim 1, wherein:
the first row of cells comprises a third cell;
the second row of cells comprises a fourth cell;
the first cell comprises a first four-track (4T) cell;
the second cell comprises a first three-track (3T) cell;
the third cell comprises a second 3T cell; and
the fourth cell comprises a second 4T cell.

12. The chip of claim 11, wherein the second tracks and the one of the first tracks provide signal routing for the second 4T cell.

13. The chip of claim 12, wherein three of the first tracks provide signal routing for the second 3T cell.

14. A chip, comprising:
a first row of cells including a first cell;
a second row of cells including a second cell, wherein the second row of cells is adjacent to the first row of cells;
first tracks providing signal routing for the first cell, wherein each of the first tracks extends in a first direction, and one of the first tracks overlaps the second cell; and
second tracks providing signal routing for the second cell, wherein each of the second tracks extends in the first direction.

15. The chip of claim 14, wherein a number of the first tracks is greater than a number of the second tracks.

16. The chip of claim 14, wherein the first cell comprises a four-track (4T) cell and the second cell comprises a two-track (2T) cell.

17. The chip of claim 14, wherein the first cell comprises a five-track (5T) cell and the second cell comprises a three-track (3T) cell.

18. A chip, comprising:
a first row of cells including a first cell;
a second row of cells including a second cell, wherein the second row of cells is adjacent to the first row of cells;
a first rail;
a second rail;
a third rail;
first tracks providing signal routing for the first cell, wherein each of the first tracks extends in a first direction, and the first tracks are disposed between the first rail and the second rail in a second direction perpendicular to the first direction; and
second tracks providing signal routing for the second cell, wherein each of the second tracks extends in the first direction, the second tracks are disposed between the second rail and the third rail in the second direction, and a number of the second tracks is greater than a number of the first tracks.

19. The chip of claim 18, wherein the first cell comprises a three-track (3T) cell and the second cell comprises a four-track (4T) cell.

20. The chip of claim 18, wherein:
the first cell comprises a first diffusion region extending in the first direction; and
the second cell comprises a second diffusion region extending in the first direction, wherein the first diffusion region and the second diffusion region have equal widths in the second direction.
